(19) United States
(12) Patent Application Publication
(10) Pub. No.: US 2012/0118359 A1
(43) Pub. Date: May 17, 2012

(54) INSULATING GLASS COMPOSITE COMPRISING DIAGONALLY ARRANGED PHOTOVOLTAIC CELLS, AND METHOD FOR THE PRODUCTION AND USE THEREOF

(75) Inventor: Rene Battistutti, Klagenfurt (AT)

(73) Assignee: ENERGETICA HOLDING GMBH, Klagenfurt-Viktring (AT)

(21) Appl. No.: 13/321,206

(22) PCT Filed: Apr. 17, 2010
(86) PCT No.: PCT/EP2010/002375

§ 371 Date: Feb. 2, 2012

(30) Foreign Application Priority Data
May 20, 2009 (DE) 10 2009 022 125.5

(51) Int. Cl. H01L 31/0203

(52) U.S. Cl. 136/251

(57) ABSTRACT

A solar module consists of a plurality of solar cells which are arranged in an insulating glass composite in the gap between a front and rear pane, said cells being fixed therein, wherein the solar cells are arranged diagonally to the vertical axis inside an approximately vertical (upright) insulating glass module which is fixed in or on an approximately vertical building facade.

Solar cells are interconnected individually or as groups in photovoltaic systems, small consumer equipment not dependent on power supply systems, or as a power supply source for outer space vehicles.

A solar module is characterized by its electrical connected value (e.g. open circuit voltage or short circuit current). These depend on the characteristics of the individual solar cells and the interconnection of the solar cells within the module.

In order to fulfill the demands of a system for solar generated power, one combines solar cells by means of numerous different materials to form a solar module. This combination fulfills the following aims:
Transparent, radiation and weather proof cover
Robust electrical connections
Protection of the brittle solar cells from mechanical effects
Protection of the solar cells and electrical connections from moisture
Sufficient cooling of the solar cells
Protection against contact with the electroconductive components
Handling and mounting possibilities

There are different models of solar modules with different types of solar cells. In the following, the design shall be explained using the types of modules most frequently used worldwide:
A pane of glass (usually the so-called single pane safety glass, or toughened glass) on the surface facing the sun.
A transparent synthetic layer (ethylene-vinyl acetate (EVA) or polyvinyl butyral (PVB) or modified EVA foils, e.g. EVM-rubber Levamelt from Lanxess (Lanxess EP1417097B1), in which the solar cells are embedded,
Mono or polycrystalline solar cells or flexible solar cell modules electrically interconnected by means of solder strips,
Rear surface lamination with a weatherproof synthetic composite film, e.g. made of polyvinyl fluoride (Tedlar) and polyester, e.g. Icosolar from Isovolta (EP00655976B1) or a glass plate,
A connection port with a flyback diode or bypass diode and a connection terminal
An aluminum profile frame to protect the glass plate during transportation, handling and installation, for the mounting and reinforcement of the composite structure, or without a frame as well.

An assembly unit of solar-photovoltaic cells is described in DE202008003967U1, which is disposed in an insulating glass composite. The assembly unit is disposed between two panes, sealed by means of an encompassing sealing strip to form a sealed hollow chamber.

The thin-film photovoltaic cells are attached to the inner surface of the insulating glass composite by means of an adhesive. With this, however, there are the disadvantages of undesired emissions of gasses from the adhesive in the inner chamber, and an elaborate assembly.

In general, thin-film PV cells, such as those specified in this utility model, are constructed in a single-cell manner—because the associated serial/parallel circuitry can already be implemented in the thin-film layout. If two or more thin-film cells are disposed in an insulating glass composite, then for the most part, the transparency is decisive, such that in, for example, no thin-film cells can be disposed a central region, in order that the insulating glass composite can also be used as a window.

A solar cell string is proposed in EP00499075B1, in which separate solar cells spaced at a distance to one another are connected in series by means of contact elements, allowing for a relative motion between the cells.

In a typical embodiment, for example, that specified in EP01018166B1, solar cells connected and toggled in series, or parallel, respectively, are provided with an encapsulating material, for example, and typically, EVA (ethylene-vinyl acetate) on each side in a lamination machine.

With the prior art described above there is the disadvantage of an elaborate installation process and mounting of the solar cells by means of lamination on associated supporting plates.

Furthermore, integration in a vertical, or nearly vertical building facade has not been taken into consideration. For building facades provided with windows and other openings, it is, however, important to integrate modules of this type in the facades for the purpose of generating power, without compromising the appearance of the facade, and furthermore, to create the possibility of allowing one to look out from the interior of the building through the solar modules integrated in the facade.

For this reason, the invention assumes the objective of mounting a plurality of solar cells according to DE202008003967U1 in such a manner that integration in a vertical or nearly vertical building facade is possible.

To attain said objective, the invention is characterized by the technical teachings of claim 1.

The main characteristic of the invention is that the solar cells are disposed at an angle to vertical in the interior of a basically vertical (upright) standing insulating glass body, said insulating glass body being mounted in or on a nearly vertical building facade.

The insulating glass body comprises an insulating glass module, consisting of, for its part, at least one front pane and at least one, spatially distanced, rear pane and an interior chamber, in which the solar cells are disposed.

The interior chamber is preferably filled with an inert gas, and the solar cells are fixed by means of soldering to the inner surface of at least one of the panes.

By means of the diagonally disposed solar cells a favorable angle of entry for sunlight is obtained with a vertical disposition of the insulating glass composite in a building facade.

The invention makes use of mono- or multi-crystalline modules, i.e. c-Si cells or other photovoltaic cells, in particular, small unit cells. These solar cells may also be designed to be flexible, and organic solar cells (e.g. Konarka), or particulate solar cells (Nanosolar, SSP Spheral Solar ATS, Taiyo Yuden, Kyocera, etc.), or respectively, piecemeal or cellular thin-film solar cells with an a-Si, a-Si-tandem, CIS, CIGS (copper indium gallium diselenide), etc. base, may be used.

c-Si cells have dimensions of, e.g. from 157×157 mm to approx. 120×120 mm and can be disposed on glass, depending on the solder support points provided therein, at nearly any point, wherein the angle is dictated by the size of the cells and the distance separating the two glass panes of the insulating glass composite. The typical separations in the interior chamber between the glass panes lie in the range of less than 5 mm to over 30 mm.

Contingent on the limited separation between the panes of a maximum of 35 mm in comparison to an edge length of 15.7 cm of the solar cell, its angle position in the interior chamber of the insulating glass module is necessary for obtaining a limited installation depth of the insulating glass module in the building facade.

As a result of the disposition of the vertical spacing of the individual, scale-like configuration of the solar cells disposed above one another and their positioning, a transparency can be obtained from the interior of the building outwards through the insulating glass module in certain regions. In reverse, transparency for light entering the building of, for example, 20% is obtained.

The scale-like disposition of the individual solar cells mounted at an angle should be obtained such that, to the greatest degree possible, the solar cells do not cast shadows in the regions of the horizontal edges.

It is, however, preferred when the mutually vertical spacing of the scale-like solar cells disposed above one another is selected such that a transparency range results in the manner of a venetian blind. Accordingly the scale-like solar cells do not overlap, but instead, allow stripes of transparency between one another.

In addition, the serial and parallel circuitry can likewise be freely selected, according to the optimal respective application. As a result, the solar modules according to the invention can also be produced as (building) windows with a satisfactory optical transparency.

The circuit points can of course be disposed directly quite simply and thermally attached to the inner surface of the glass through the hollow profile with its primary and secondary insulations to the exterior. Potential diodes or resistors can therein also be readily integrated.

Therein is the substantial advantage that with the angled disposition of the solar cells in the interior space of an insulating glass module of this type, a good mounting, with an optimal angle to the sun, is provided, as it is now possible to dispose the solar cells simply on the inner surface of the rear pane at an angle, wherein the mounting at the raised end is also the electrical contact. A simple anchoring or attachment is sufficient, such as by means of drops of adhesive or solder, that are, for example located at the lower ends of the solar cells, forming an adhesion to the inner surface of the rear pane.

In the present invention, wedge shaped solar cell modules of, for example, 15.7 cm squares are used, having edge elements or bands that can be soldered and have good electrical conductivity, connecting the lower surface of a cell with the upper surface structure of a cell connected to said serially, and as a result forming the connections of a module. The type of serial and parallel circuitry for this can be selected from the prior art, and the number of said connecting bands (strings) can also be selected from the prior art, whereby two strings is typical.

In another embodiment of the invention, it is provided that the strings connecting the cells are soldered to the inner surface of the rear pane to fix the cells in place.

In this manner a particularly simple mounting is obtained and thereby a simple installment as well of insulating glass modules of this type with only the attached solar cells serving as positioning anchors therein.

For this reason, additional lamination is no longer necessary and the solar cells can be inserted at an angle in a, so to speak “Snow White's coffin,” and held in place securely therein.

According to the invention, the interior chamber is designed as a hollow chamber and is filled with an inert gas, preferably argon. This differs from the prior art in that with the prior art it is provided, for electrical reasons, that the outer surface of solar cells is entirely covered with a synthetic layer, which is optically permeable, i.e. transparent or translucent, and serving as the mounting for the solar cells, and reducing the glare of incident light.

Said is eliminated in the present invention, resulting in a significant cost reduction. The prior art relates to a so-called EVA coating (ethylene-vinyl acetate).

According to the invention, this is eliminated, and as a result, the production costs of a photovoltaic element of this type are significantly reduced. At the same time, as a result of the angled position, the loss of efficiency resulting from any reflection on the inner pane of glass facing the sun, or respectively, the surface of the solar cells, is compensated for, or respectively, the overall efficiency is greater than that of comparable solar cells integrated vertically in building facades.

As a result of the elimination of the coating synthetic covering of the solar cells, the danger of reflection in the interior space of the insulating glass module exists, and thereby a loss of efficiency. In order to reduce this, it is provided that on the outer surface of the front pane an antiglare coating is applied. Likewise, an embossed pattern can also be used on the outer surface of the front pane. Of primary importance, however, is the angled positioning of the solar cells enabling an increase to the overall efficiency.

A further substantial characteristic of the invention is that due to the incorporation of the solar cells in an insulating glass module, it is essential that the insulating glass module be sealed entirely, and filled with the aforementioned inert gas, in particular argon, or provided with a vacuum. For this it is provided that an encompassing hollow profile is disposed on the edge that, firstly, is attached to the inner surfaces of the front and rear panes by means of an adhesive, and having a sealing means on its surface that fully holds and sustains the spacing profile in a sealed manner in the interior space between the front pane and the rear pane.

In a first embodiment of the present invention, the solar cells are positioned at an angle solely by means of an adhesive glue on the inner surface of the rear pane.

In a second embodiment, the solar cells are soldered at their strings to dedicated conductor screens, disposed on the surface of the rear pane, whereby the strings are raised on one side, or a spacing element with the electrical contact function is built in.

The invention also provides for a combination of the two aforementioned positioning anchors.

It is of particular advantage that these conductor screens can also be applied from the edges and serve the incoming and outgoing current of the conductor to the exterior.

A preferred method for the production of a photovoltaic module of this type comprises the following production steps:
1. Production of a conventional solar cell with an electrical connection for the dedicated strings, such that said photovoltaic module is electroconductive and functional.
2. Insertion of said prepared, fully functional, photovoltaic module in an open insulating glass composite at an angle, wherein the front pane is still absent and at least the spacing on one side of the individual photovoltaic cells must be given.
3. The solar cells placed on the rear pane are affixed to the rear pane by means of a suitable anchoring adhesive and the incoming and outgoing leads are produced by means of soldering to a conductor screen capable of accepting soldering on the inner surface of the rear pane.
4. Application of the hollow profile encompassing the periphery with at least one adhesive for attaching the hollow profile to the inner surface of the rear pane.
5. Application of the front pane to the prepared hollow profile by sticking the inner surface of the front pane to the adhesive on the hollow profile.
6. Application of a sealant encompassing the perimeter for sealing the hollow profile in the insulating glass composite between the front pane and the rear pane.
7. The interior space in the insulating glass module is filled with an inert gas, in particular argon, or provided with a vacuum.

In a second method variation, all production steps are executed as stated above, with the exception of the production step in which the solar cells are positioned with an adhesive glue to the inner surface of the rear pane.

Instead, the strings, serving as the electrical connection for the solar cells, are attached to dedicated conductor screens capable of being soldered, with the aid of a solder or friction welded connection, on the inner surface of the rear pane.

The invention subject matter of the present invention is derived not only from the subject matter of the individual claims, but also from combinations of the individual claims.

All characteristics in the documents, including the information disclosed in the abstract, in particular the spatial designs shown in the illustrations, are claimed as fundamental to the invention insofar as they are, individually or in combination, novel in comparison to the prior art.

In the following, the invention shall be explained in greater detail using the illustrations showing numerous means of execution. Herein, further characteristics and advantages fundamental to the invention can be derived from the illustrations and their description.

They show:

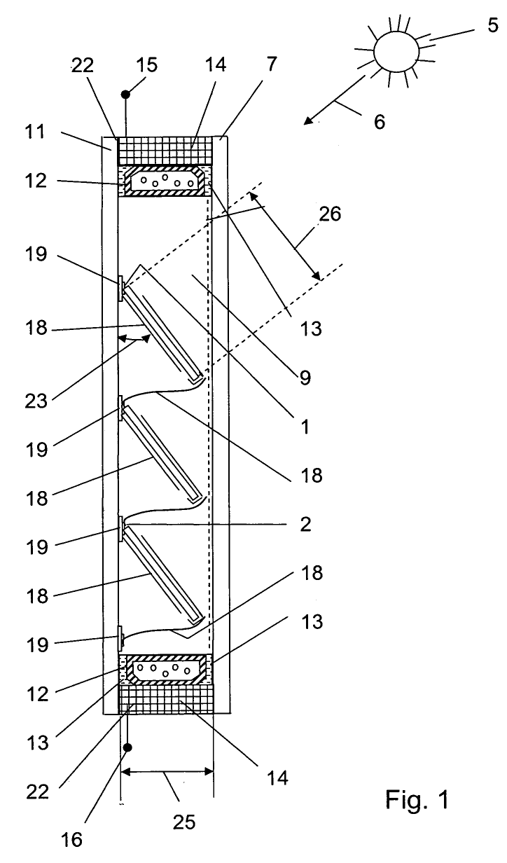

FIG. 1: The schematic cross-section through an insulating glass module with solar cells (1, 2) disposed at an angle,

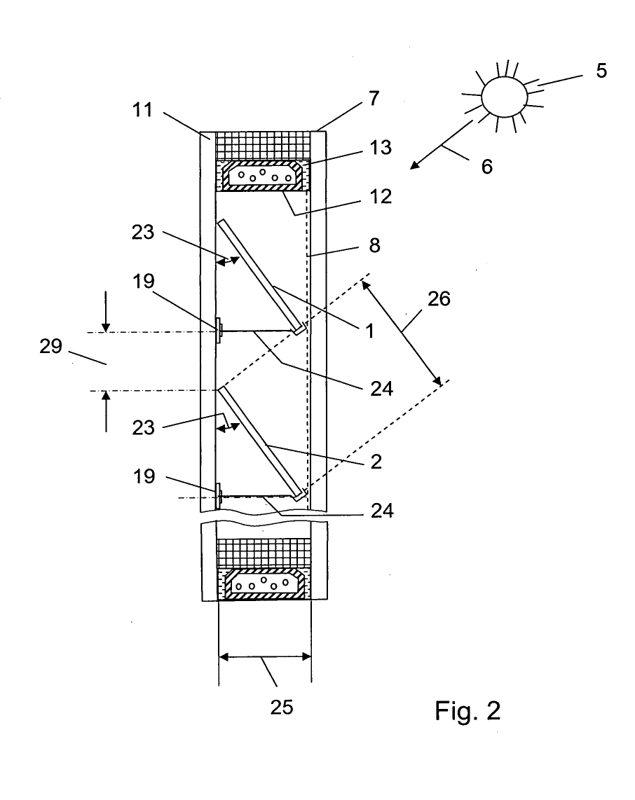

FIG. 2: The schematic cross-section through an insulating glass module with solar cells (1, 2) disposed at an angle with angle elements (24).

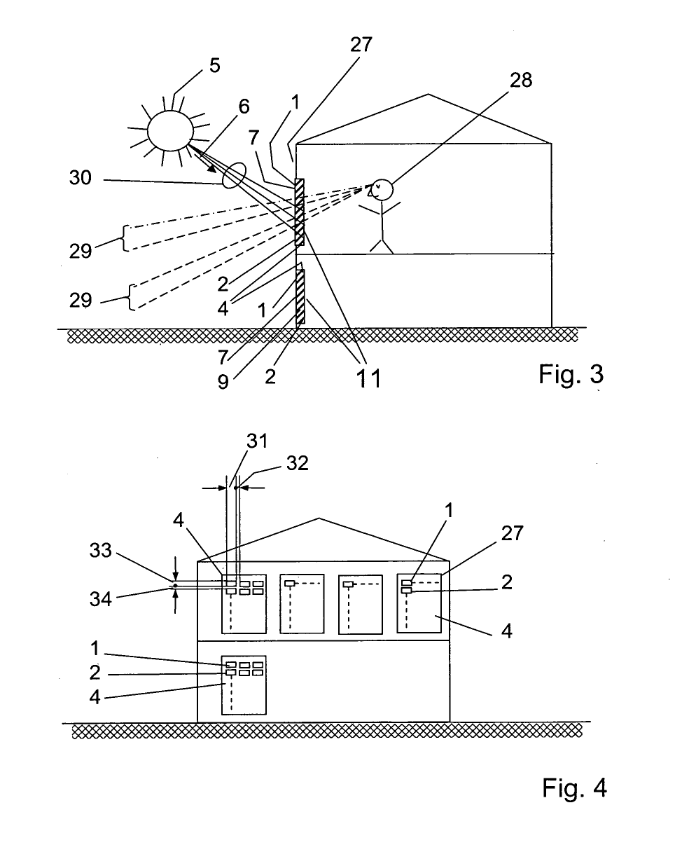

FIG. 3: The schematic cross-section through a building with the insulating glass module integrated in the facade.

FIG. 4: The front view of the building facade according to FIG. 3.

FIG. 1 shows a schematic cross-section through an insulating glass module with solar cells 1, 2 disposed at an angle, consisting of two interconnected solar cells 1, 2, which are connected to one another by means of strings 18 (not shown) in an electroconductive manner. Each solar cell 1, 2 consists of numerous electrically connected individual cells 3. In the framework of the present invention, the different types of circuitry for these solar cells shall not be explained in greater detail.

It is important here that the solar cells 1, 2 are anchored in an insulating glass module 4, wherein the solar cells 1, 2 are placed on a rear pane 11 made of glass and by means of an adhesive (not shown) attached to the surface of said rear pane 11. The strings 18 are interconnected in a electroconductive manner for this and lead outwards under the hollow profile 12 at their ends. In this manner, the connections 15, 16 are able to establish an electric contact.

After the anchoring of the solar cells 1, 2 to the inner surface of the rear pane 11, the hollow profile 12 is then inserted and glued to the inner surface of the rear pane 11 by means of a suitable adhesive 13. Subsequently the front pane 7 is placed in position, which is also glued to the hollow profile 12 by means of a suitable adhesive 13. The adhesive 13 is designed such that it is thermally elastic and allows for a certain amount of movement of the two panes 7, 11 in relation to one another.

A sealant 14 is then applied to the periphery of the edges, connecting the hollow profile 12 with the panes 7, 11 in a sealing manner and thereby forming a fully sealed, i.e. airtight, connection, such that the interior space 9 of the insulating glass module 4 is sealed from the atmosphere. As a result, no vapor can permeate the interior space 9, in particular because a suitable drying agent 17 is disposed in the hollow profile 12 and by means of appropriate air channels has access to the interior space 9 of the insulating glass module 4.

A coating 8 may be provided on the inner surface of the front pane 7, designed as an antiglare coating.

In applying the front pane 7 to the adhesive 13 and the sealing with the sealant 14, an air exchange to the atmospheric air present in the interior space 9 with an inert gas can be carried out, or as a rule, the air may remain in the interior space 9, or the interior space may be provided with a vacuum.

A corresponding radiation from the sun 5 in the direction of the arrow 6 to the front pane 7 of the insulating glass module 4 results in a suitable irradiation of the interior space 9, whereby the outer coating 10 on the outer surface of the front pane 7 prevents reflection directed outwards. As a result, excellent lighting in the interior space 9 is obtained through the transparent or translucent front pane 7 onto the solar cells 1, 2, which therefore function at a high degree of efficiency. There is no danger of becoming soiled, or of the formation of water vapor.

Signs of aging are minimized due to the encasing of the solar cells in dry air or an inert, dry gas. This provides the solar cells with a long life expectancy at a high degree of efficiency. The solar cells lie, so to speak, freely in an “Snow White's coffin,” without being covered by a substantially diffuse, luminosity reducing, cover layer, as a result of which this entire configuration functions at a higher degree of efficiency.

The solar cells (1, 2) can, for this, be placed at an angle corresponding to the available space (25) between the two glass panes (7, 11) and the dimensions (26) of the solar cells (1, 2).

In a simple embodiment, the angle position (23) can be obtained by means of the string elements (18). The string (18) on the lower surface of the cell can thereby be attached by means of soldering or ultrasound, or friction welding, respectively, to a conductor screen (19), and the string element (18) on the upper surface can be guided to, and make contact with, another element of the conductor screen (19) at an appropriate angle and spacing.

In this case, the electrical wiring and the mechanical attachment, including the adjustment of the angle position (23), can be attained by means of the string element (18).

As a rule, the attachment of the solar cells (1, 2) can also be achieved by means of glue elements separately from the string contact (18, 19). For this, the cells are first fixed in position by means of glue elements and subsequently the contact is established between the string elements (18) and the conductor screen (19).

The string elements (18) do not need, in each case, to extend over the entire length (26) of the solar cells (1, 2), but rather it is also possible to use piecemeal string elements (18) with an appropriately large cross-section and thereby a corresponding mechanical stability.

The configuration of the solar cells (1, 2), or the spacing of the solar cells (1, 2) at a distance from one another, and their angle position, is selected such that a maximum of solar radiation (arrow direction 6) conversion to electric energy is provided. As a result of the angle position (23) and the vertical separation of the solar cells (1, 2) arranged in an arrow shape in relation to one another, a type of venetian blind effect is obtained and a downwards or horizontal transparency 29 is obtained, as is, in particular, visible in FIG. 4.

As a rule, the angle position (23) may also be variable, and the angle (23) can be manually or automatically regulated.

A schematic cross-section through an insulating glass module with solar cells (1, 2) disposed at an angle using angle elements (angle position elements 24) is shown in FIG. 2.

In this embodiment, the solar cells (1, 2) are positioned on the glass pane (11) by means of individual angle position elements (24) with the string elements (18), and subsequently, the electrical contact (18, 19) is established.

The angle position elements (24) may be made of thermoplastic or thermosetting synthetics or from metal or ceramics or a combination of these materials, and individual elements or multiple elements, or multiple objects, may be used. As a result, the assembly can be simplified and thereby accelerated.

Typical solar cells (1, 2) have a small inactive edge, which can be used therefore with no loss to efficiency for an edge attachment.

Furthermore, solar cells (1, 2) can be used having strings (18) with established contact, and connected as such serially, and said can be placed on the glass pane (11) with the angle position elements (24) and subsequently anchored.

The angle position elements (24) can be attached by means of gluing or soldering to an underlying conductor screen (19) on the glass surface (11), and the angle position elements (24) may also be designed such that the other end of the solar cells (1, 2) can be positioned, or easily snapped into position and in this manner the solar cells (1, 2) are already fixed in their angle position (23).

FIG. 3 shows a schematic cross-section through a building that has insulating glass modules (4) with integrated solar cells (1, 2). The maximum angle position of the individual solar cells (1, 2) in the interior space (9) is determined by the size of the solar cells (1, 2) and the distance separating the two glass panes (7, 11). The spacing of the solar cells (1, 2) is preferably selected such that at a certain position of the sun (5) the solar radiation (30) to the individual solar cells (1, 2) takes place with no, or for the most part no shadows being cast onto other solar cells (1, 2).

As a result of this spacing in a scale-like manner of the solar cells above one another, a certain transparency (29) is provided for a person (28) in the interior of the building, whereby the transparency (29) is provided downwards, and not upwards, or towards the sun (5). In this manner, a venetian blind type effect is obtained with half closed, or, respectively, half open slats. The transparency 29 can furthermore be obtained through the lateral separation of the individual solar cells 1, 2, whereby this may amount to a range of from a few millimeters to several centimeters. Depending on the spacing selected, a more limited conversion efficiency of solar energy to electric energy per surface unit will be obtained.

FIG. 4 shows a schematic front view of a building facade (27). For this, individual insulating glass elements (4) with differing solar cells (1, 2) are shown from the front. The width (31) of the solar cells (1, 2) is dependent for the most part on the type of solar cell selected, and the spacing (32) can be designed according to architectural desires, and in this manner the transparency can be selected to be greater or lesser.

The height (33) of the solar cells (1, 2) positioned at an angle is determined by the actual height or length (26) of the solar cells (1, 2) and the distance separating the two glass panes (7, 11), or by the angle position (23) of the solar cells, respectively. The spacing (34) separating the solar cells (1, 2) arranged above one another is generally a positive value, amounting to a few millimeters and is selected such that the solar cells do not cast shadows onto one another.

Reference Number Legend

| | |
|---|---|
| 1 | Solar cell |
| 2 | Solar cell |
| 3 | Individual cell |
| 4 | Insulating glass module |
| 5 | Sun |
| 6 | Arrow direction |
| 7 | Front pane |
| 8 | Coating (interior) |
| 9 | Interior space |
| 10 | Coating (exterior) |
| 11 | Rear pane |
| 12 | Hollow profile |
| 13 | Adhesive |
| 14 | Sealant |
| 15 | Connection |
| 16 | Connection |
| 17 | Drying agent |
| 18 | String |
| 19 | Conductor screen (can be soldered) |
| 20 | Thermal anchor |
| 21 | Solder connection |
| 22 | Connection surface |
| 23 | Angle (angle position) |
| 24 | Angle position element |
| 25 | Glass separation |
| 26 | Length of the solar cell (2) |
| 27 | Building facade |
| 28 | Person |
| 29 | Transparency |
| 30 | Solar radiation with respect to PV-cell |
| | shading |
| 31 | Width of the individual solar cells |
| 32 | Horizontal separation of the solar cells |
| 33 | Height of the angled solar cells |
| 34 | Spacing of the solar cells disposed |
| | above one another |

1. A solar module consisting of a plurality of solar cells disposed in an insulating glass composite in the space between a front and rear pane said cells being fixed therein, wherein the solar cells are disposed at an angle to the vertical plane in the interior space of a substantially vertical (upright) standing insulating glass module, said insulating glass module can be mounted in or on a nearly vertical building facade, and wherein the individual solar cells respectively, are disposed in vertically spaced horizontal rows at a vertical spacing of several millimeters and thereby providing a horizontal transparency, characterized in that for further horizontal transparency the individual solar cells have a lateral horizontal spacing of between a few millimeters to several centimeters between said.

2. The solar module according to claim 1, characterized in that the solar cells are placed on the inner surface of the rear pane at an angle, wherein the support at the raised end is also the electrical contact.

3. The solar module according to claim 1, characterized in that solar cells connecting strings are soldered to the inner surface of the rear pane to secure the solar cells in position.

4. The solar module according to claim 1, characterized in that solar cells are only fixed in position at an angle with an adhesive glue on the inner surface of the rear pane.

5. The solar module according to claim 4, characterized in that the angle position of the solar cells is formed by means of the string elements such that the string on the lower surface of the cell is attached to a conductor screen of the rear pane by means of soldering or ultrasound, or through friction welding, and the string element on the upper surface of the cell is connected, with the angle and spacing, to a further element of the conductor screen, thereby making contact.

6. The solar module according to claim 1, characterized in that the angle position of the solar cells can be varied and the angle can be adjusted manually or automatically.

7. The solar module according to claim 6, characterized in that the solar cells are positioned with the string elements by means of individual angle position elements on the glass pane.

8. The solar module according to claim 1, characterized in that the height of the solar cells in the vertical direction is greater that the space separating the panes of the insulating glass module in the horizontal direction.

9. The solar module according to claim 8, characterized in that with a vertical height of 157 mm of the solar module, the slight separation between the panes is between 5 mm and 50 mm.

10. The solar module according to claim 1, characterized in that the interior space between the panes contains a vacuum, or is filled with inert gas, in particular, argon.

11. The solar module according to claim 1, characterized in that and antiglare coating is applied to the upper surface, the inner surface and or the outer surface of the front pane.

12. The solar module according to claim 1, characterized in that an embossed structure is used on the surface of the front pane.

13. The solar module according to claim 2, characterized in that the angle position of the solar cells can be varied and the angle can be adjusted manually or automatically.

14. The solar module according to claim 13, characterized in that the solar cells are positioned with the string elements by means of individual angle position elements on the glass pane.

15. The solar module according to claim 2, characterized in that the height of the solar cells in the vertical direction is greater that the space separating the panes of the insulating glass module in the horizontal direction.

16. The solar module according to claim 2, characterized in that the interior space between the panes contains a vacuum, or is filled with inert gas, in particular, argon.

17. The solar module according to claim 2, characterized in that an embossed structure is used on the surface of the front pane.

18. The solar module according to claim 4, characterized in that the angle position of the solar cells is formed by means of the string elements such that the string on the lower surface of the cell is attached to a conductor screen of the rear pane by means of soldering or ultrasound, or through friction welding, and the string element on the upper surface of the cell is connected, with the angle and spacing, to a further element of the conductor screen, thereby making contact.
